(19) United States
(12) Patent Application Publication
(10) Pub. No.: US 2025/0246441 A1
(43) Pub. Date: Jul. 31, 2025

(54) METHOD FOR ATTACHING DISCRETE POWER MODULES TO A SUBSTRATE

(71) Applicant: Ford Global Technologies, LLC, Dearborn, MI (US)

(72) Inventors: Russell Lee Weatherspoon, Holly, MI (US); Shreyas Raman, Dearborn, MI (US); Brandon Dobbins, Grosse Pointe Park, MI (US); Ross Evers, Tecumseh, MI (US); Venkatesh Radhakrishnan, Canton, MI (US); Ethan Martin, Dearborn, MI (US)

(73) Assignee: Ford Global Technologies, LLC, Dearborn, MI (US)

(21) Appl. No.: 18/424,247

(22) Filed: Jan. 26, 2024

(51) Int. Cl. H01L 21/48; H01L 21/60; H01L 21/673; H01L 21/768

(52) U.S. Cl. CPC H01L 21/4853; H01L 21/60; H01L 21/67333; H01L 21/76882; H01L 2021/60135

(57) ABSTRACT

A method of attaching a plurality of discrete power modules (DPMs) to a substrate includes positioning the substrate such that a bottom surface of the substrate opposes a top surface of a base plate. The method includes placing solder pre-forms on a top side of the substrate, placing each DPM on a top surface of a corresponding solder pre-form, and performing a reflowing process. The reflowing process includes melting the solder pre-forms by providing heat to the substrate via the base plate. The method further includes measuring, via at least one sensor, measured temperatures of a plurality of temperature zones of the DPMs during the reflowing process. The method includes determining, via a controller, whether the measured temperatures of the plurality of temperature zones are below a threshold temperature during the reflowing process and maintaining the measured temperatures of the temperature zones below the threshold temperature during the reflowing process.

### FIELD

The present disclosure relates to attaching discrete power modules to a substrate.

### BACKGROUND

The statements in this section merely provide background information related to the present disclosure and may not constitute prior art.

Electric vehicles require inverters to manage the electric drive system. The inverters utilize discrete power modules (DPMs) or a non-discrete power module assembly to perform pulse width modulation (PWM) to transform direct current (DC) power from a battery or energy storage system to alternating current (AC) power for vehicle systems such as the electric motors that propel the vehicle. In some applications, a silver sintering process is used to attach DPMs to a substrate in the inverter. The silver sintering process is an alternative to traditional soldering that involves heating a silver powder paste to transform the silver powder to a solid without going through a liquid stage. Traditional soldering involves applying a flux to a joint at which the components are to be attached and then heating the components while simultaneously applying solder to the components at the joint so that the solder melts and flows into the joint. In other solder applications a solder paste is used, in which the paste contains solder balls and flux. The solder paste is then melted, and a sticky flux residue is left behind and is managed by a flux management system and cleaning schedule. The flux left behind in solder paste applications can increase voids in the solder joint. Some DPMs are molded in an epoxy or polymer that has a peak temperature (e.g., a peak temperature of 240° C. to 260° C.) above which excessive delamination of the molding may occur. Such excessive delamination can render the DPM defective or reduce its lifespan. To create more robust thermal interface and a solid mechanical joint at the DPM and substrate interface when soldering DPMs, solder materials with higher liquidus temperatures are needed. Unfortunately, the liquidus temperatures of suitable solder materials may approach the peak temperature at which such excessive epoxy molding delamination may occur.

The present disclosure addresses these and other issues with attaching DPMs to a substrate of a power inverter.

### SUMMARY

This section provides a general summary of the disclosure and is not a comprehensive disclosure of its full scope or all of its features.

In one form, the present disclosure provides a method of attaching a plurality of discrete power modules (DPMs) to a substrate includes positioning the substrate such that a bottom surface of the substrate opposes a top surface of a base plate. The method includes placing a plurality of solder pre-forms on a top side of the substrate, placing each DPM of the plurality of DPMs on a top surface of a corresponding solder pre-form of the plurality of solder pre-forms, and performing a reflowing process. The reflowing process includes melting the solder pre-forms by providing heat to the substrate via the base plate. The method further includes measuring, via at least one sensor, measured temperatures of a plurality of temperature zones of the DPMs during the reflowing process. The method includes determining, via a controller, whether the measured temperatures of the plurality of temperature zones are below a threshold temperature during the reflowing process. The method also includes maintaining the measured temperatures of the plurality of temperature zones below the threshold temperature during the reflowing process.

In variations of the method of the above paragraph, which can be implemented individually or in any combination: the maintaining the measured temperatures below the threshold includes dynamically adjusting a power supplied to the base plate to lower a base plate temperature of the base plate; the maintaining the measured temperature below the threshold further includes dynamically increasing a hold time of the base plate temperature; the maintaining the measured temperature below the threshold includes dynamically decreasing a hold time of a base plate temperature of the base plate; the method further includes dispensing a tacking agent (a) between the top side of a substrate and the plurality of solder pre-forms to retain the plurality of solder pre-forms on the substrate, or (b) between each DPM and the top surface of the corresponding solder pre-forms of the plurality of solder pre-forms to retain the DPMs on the plurality of solder pre-forms, or (c) (a) and (b); the method further includes placing a tray between the substrate and a plurality of busbars electrically coupled to each of the DPMs of the plurality of DPMs, wherein the tray provides at least one of electrical insulation between the busbars and the substrate, and reaction support for a clamp force applied to the busbars; the method further includes placing an alignment fixture such that the plurality of DPMs are between the alignment fixture and the substrate, and applying a force to the alignment fixture toward the substrate such that the alignment fixture clamps the plurality of DPMs to the substrate during the reflowing process; the substrate is a material having a first coefficient of thermal expansion and the alignment fixture is a material having a second coefficient of thermal expansion, the second coefficient of thermal expansion being within ±7.0*10⁻⁶ m/(m*° C.) of the first coefficient of thermal expansion; the alignment fixture defines a plurality of apertures, each aperture of the plurality of apertures aligning with a corresponding DPM of the plurality of DPMs and being open through the alignment fixture such that the DPMs are visible through the apertures, wherein the alignment fixture contacts a plurality of perimeter regions of each DPM; the plurality of perimeter regions includes four corners of each DPM; the bottom surface of the substrate contacts the top surface of the base plate during the reflowing process; the bottom surface of the substrate is disposed a predefined distance above the top surface of the base plate during the reflowing process; the at least one sensor includes at least one non-contact sensor; the at least one sensor includes three sensors and the plurality of temperature zones includes three temperature zones, wherein each sensor of the three sensors is positioned to measure a corresponding one of the three temperature zones; the reflowing process occurs within at least one chamber and the reflowing process further includes filling the at least one chamber with a gaseous substance including HCOOH, increasing a pressure of the gaseous substance to be between 750 and 1050 mbar in the at least one chamber, and heating the base plate to increase the measured temperatures of the plurality of temperature zones to be between 215 and 265 degrees Celsius for a first hold time while the pressure is between 750 and 1050 mbar.

In another form, the present disclosure provides for a method of attaching a plurality of discrete power modules (DPMs) to a substrate including positioning the substrate such that a bottom surface of the substrate opposes a top surface of a base plate. The method includes placing a plurality of solder pre-forms on a top side of the substrate, placing each DPM of the plurality of DPMs on a top surface of a corresponding solder pre-form of the plurality of solder pre-forms, and performing a reflowing process. The reflowing process includes melting the solder pre-forms by providing heat to the substrate via the base plate. The method further includes measuring, via at least one sensor, measured temperatures of a plurality of temperature zones of the DPMs during the reflowing process. The method includes determining, via a controller, whether the measured temperatures of the plurality of temperature zones are below a threshold temperature during the reflowing process. The method includes maintaining the measured temperatures of the plurality of temperature zones below the threshold temperature during the reflowing process by at least one of dynamically adjusting a power supplied to the base plate to lower a base plate temperature of the base plate, and dynamically adjusting a hold time of the power supplied to the base plate.

In variations of the method of the above paragraph, which can be implemented individually or in any combination: the method further includes placing a tray between the substrate and a plurality of busbars electrically coupled to each of the DPMs of the plurality of DPMs, wherein the tray provides at least one of electrical insulation between the busbars and the substrate, and reaction support for a clamp force applied to the busbars; the method further includes placing an alignment fixture such that the plurality of DPMs are between the alignment fixture and the substrate, and applying a force to the alignment fixture toward the substrate such that the alignment fixture clamps the plurality of DPMs to the substrate during the reflowing process; the at least one sensor includes three sensors and the plurality of temperature zones includes three temperature zones, wherein each sensor of the three sensors is positioned to measure a corresponding one of the three temperature zones.

In still another form, the present disclosure provides a system including a substrate, a plurality of solder pre-forms, a plurality of discrete power modules (DPMs), an insulation tray, and an alignment fixture. The plurality of solder pre-forms are disposed on a top side of the substrate. Each DPM of the plurality of DPMS is disposed on a corresponding solder pre-form of the plurality of the solder pre-forms, and wherein each DPM includes a plurality of electrical contacts. The insulation tray is disposed between the electrical contacts and the substrate and electrically insulating the electrical contacts from the substrate. The alignment fixture is disposed on the substrate such that the plurality of DPMs are between the alignment fixture and the substrate, the alignment fixture being configured to clamp the DPMs to the substrate.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a perspective view of an electrical power component according to the present disclosure;

FIG. 2 is an exploded perspective view of the electrical power component of FIG. 1;

FIG. 3 is a flow chart of a method of assembling the electrical power component of FIG. 1, according to the present disclosure;

FIG. 4 is a perspective view illustrating the electrical power component of FIG. 1 in a preassembled state according to the present disclosure;

FIG. 5 is a perspective view of the electrical power component of FIG. 1 in another preassembled state according to the present disclosure;

FIG. 6 is a perspective view of the electrical power component of FIG. 1 in yet another pre-assembled state, illustrating an alignment fixture used in assembling the electrical power component, according to the present disclosure;

FIG. 7 is a bottom perspective view of a portion of the alignment fixture of FIG. 6;

FIG. 8 is a sectional view of the electrical power component and alignment fixture of FIG. 6;

FIG. 9 is a different sectional view of the electrical power component and alignment fixture of FIG. 6;

FIG. 10 is a flow chart illustrating more details of a step of the method of FIG. 3;

FIG. 11 is a schematic view of a system for melting solder pre-forms of the electrical power component of FIG. 1, according to the present disclosure; and

FIG. 12 is a schematic view of a system for melting solder pre-forms of the electrical power component of FIG. 1, according to another form of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

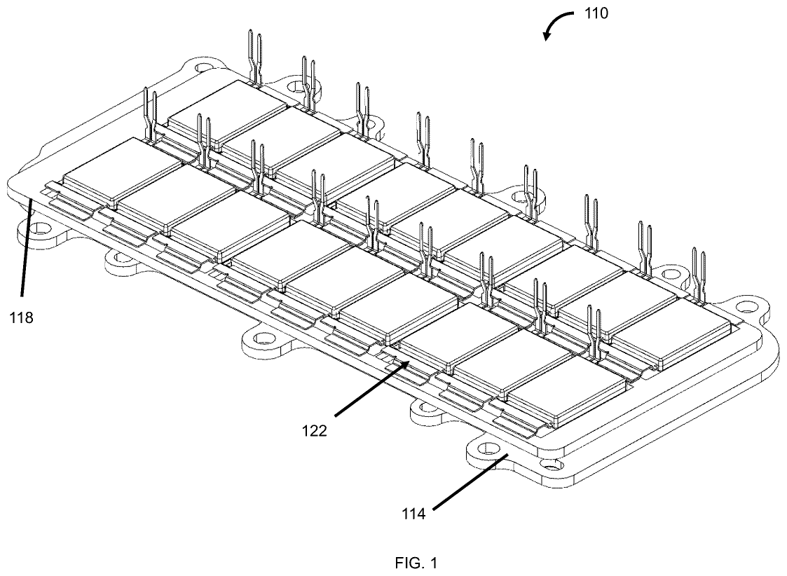

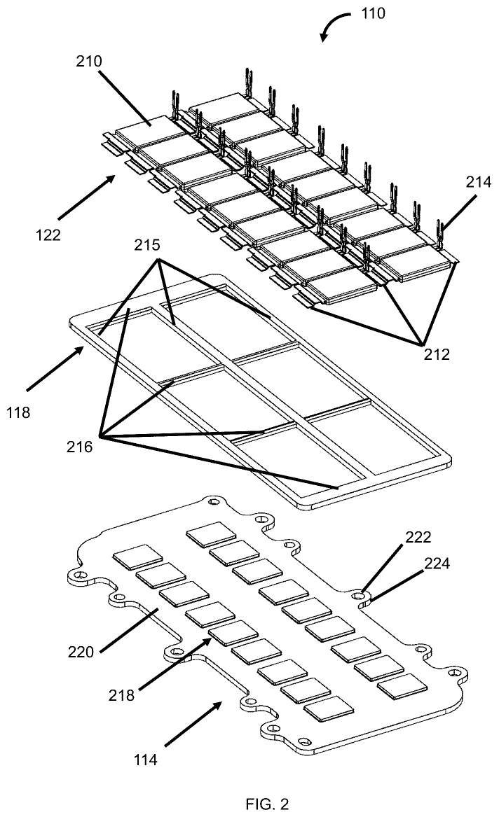

Referring to FIGS. 1 and 2, an electrical power component 110 includes a substrate 114, an insulation tray 118, and a plurality of discrete power modules (DPMs) 122. The electrical power component 110 in the example provided is a component of an inverter of an electric vehicle (not shown), though the electric power component may be used in other types of electronic devices. The inverter manages the electric drive system of the electric vehicle by transforming a direct current (DC) from the battery (not shown) to an alternating current (AC) for the electric motors (not shown) to propel the electric vehicle.

While not specifically shown, the inverter may also include a housing that encapsulates the entire electric power component 110 or may include a cover that can be coupled to the substrate 114 to encapsulate the insulation tray 118 and the DISCRETE POWER MODULEs 122 between the substrate 114 and the cover.

The discrete power modules 122 function as an electronic switching device within the inverter. Direct current from the battery flows to the inverter and the discrete power modules 122 are configured to control the direction of flow of the current to produce an alternating current for the electric motors of the vehicle. In another form, alternating current from the motors (e.g., during regeneration mode) can flow to the inverter and the discrete power modules 122 can be configured to produce a direct current to recharge the battery. The discrete power modules 122 include a housing 210, a busbar 212, and a connection pin 214. The housing 210 contains electrical components such as semi-conductor chips (not shown). The busbar 212 extends through the housing 210 and is electrically coupled to the electrical components therein. The connection pin 214 extends through the housing 210 and is electrically coupled to the electrical components therein.

The insulation tray 118 is located between the busbars 212 of the discrete power modules 122 and the substrate 114. The insulation tray 118 includes a plurality of longitudinal partitions 215 that electrically isolate the busbars 212 of the discrete power modules 122 from the substrate 114. As such, the longitudinal partitions 215 are formed of an electrically non-conductive material with a high thermal resistance such as, but not limited to, a plastic or a polymer (e.g., PA6T/XT-GF35 or PEEK). In the example provided, the entire insulation tray 118 is formed of the electrically non-conductive material, though other configurations can be used. The insulation tray 118 may also optionally include a plurality of lateral partitions 216 to aid in retaining the discrete power modules 122 during the re-flow process. The lateral partitions 216 extend laterally between the longitudinal partitions 215.

Additionally, the insulation tray 118 provides support for the discrete power modules 122 during the laser welding process. To laser weld the busbars 212 of the discrete power modules 122 a clamping force is applied to the busbars 212. The clamping force clamps the busbars 212 toward the substrate 114 so that the busbars 212 are clamped to the longitudinal partitions 215. The insulation tray 118 provides support to the undersides of the busbars 212 when the laser welding clamping tool (not shown) contacts the topsides of the busbars 212.

The substrate 114 of the electrical power component 110 functions as a heat sink within the inverter. The substrate is formed of a thermally conductive material such as, but not limited to, copper, aluminum, silver, gold. In one form, as shown in FIG. 2, the substrate 114 includes a plurality of pads 218 corresponding to the plurality of discrete power modules 122. The plurality of pads 218 extend upward from a top surface 220 of the substrate 114. In the example provided, each pad 218 is discrete from each other pad 218 such that the top surface 220 of the substrate 114 defines gaps between each pad 218, though other configurations can be used. Each of the plurality of discrete power modules 122 is aligned with and disposed on a respective pad 218 such that an underside of each discrete power module 122 is a thermal conduction relationship with its respective pad 218. The substrate 114 is configured to disperse the heat generated from the plurality of discrete power modules 122 across a larger surface area. The substrate 114 may be configured to disperse the heat to the atmosphere, a cooling medium, or to a subsequent component (e.g., a heat exchanger) to which it is attached. Additionally, during the reflowing process the substrate 114 functions as a thermal conductor, as described in greater detail below.

The substrate 114 also defines a plurality of bores 222 disposed about a periphery of the substrate 114. In the example provided, the substrate 114 defines a plurality of fingers 224 that extend outward from the periphery of the substrate 114 and the bores 222 are defined through the fingers 224, though other configurations can be used. The bores 222 can be outward of a perimeter of the insulation tray 118 such that they are accessible while the insulation tray 118 is disposed on the substrate 114. The bores 222 can be configured to receive a fastener (not shown) to mount the substrate to another component (not shown; e.g., the vehicle or another component of the inverter).

In the example provided, the discrete power modules 122 are arranged in two rows, each row extending in the longitudinal direction, though other configurations can be used. In another configuration, only a single row of discrete power modules 122 is used. In still another configuration, three or more rows are used. While the example provided includes nine discrete power modules 122 in each row, other configurations may be used. In one configuration, two or more, but less than nine, discrete power modules 122 are in each row. In another configuration, more than nine discrete power modules 122 are in each row.

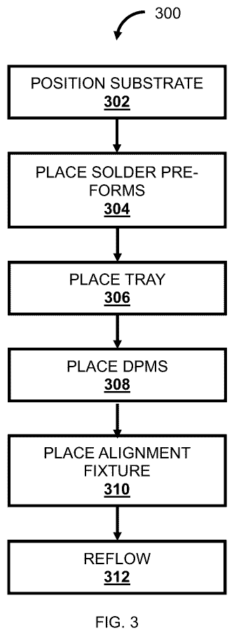

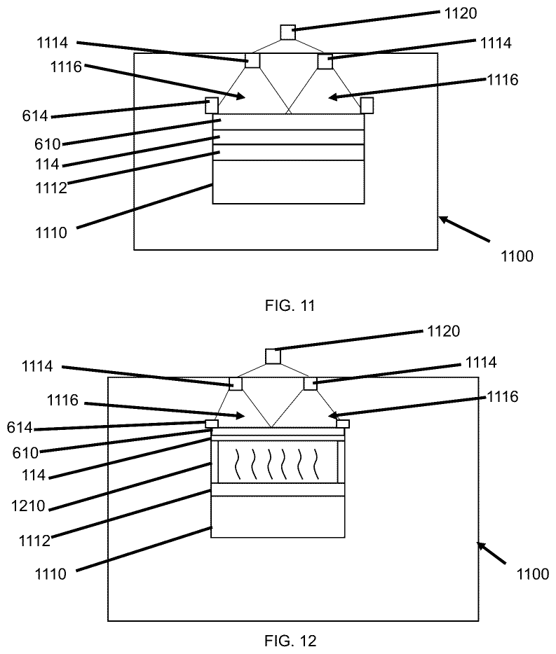

Referring to FIG. 3, a flowchart illustrating an example method 300 of assembling the electrical power component 110 is provided. In step 302 the substrate 114 is positioned relative to a base plate 1110, shown in FIG. 11 so that the base plate 1110 can provide conductive heating to the underside of the substrate 114.

Referring to FIG. 11, in the example provided, a carrier plate 1112 can optionally be disposed between the base plate 1110 and the substrate 114 such that a bottom surface of the substrate 114 opposes and is in contact with a top surface of the carrier plate 1112 and a bottom surface of the carrier plate 1112 opposes and is in contact with a top surface of the base plate 1110. In one form, the base plate 1110 includes one or more heating elements (not shown, e.g., electric resistance heating elements) that provide the heating. In another form, the base plate 1110 is heated by one or more infrared heating elements (not shown, e.g., electromagnetic radiation) that provides the heating. In another form, the base plate 1110 includes an induction heating element that heats the carrier plate 1112 via induction heating. As such, a gap may optionally be provided between the base plate 1110 and the carrier plate 1112. In an alternative form, not specifically shown, the carrier plate 1112 is omitted such that the base plate 1110 provides heating directly to the substrate 114 via conduction, infrared, or induction.

Referring to FIG. 12, in an alternative form, the substrate 114 can be spaced apart from the carrier plate 1112 by spacers 1210. In this configuration, the base plate 1110 heats the substrate 114 via radiation. In the example provided, the base plate 1110 heats the carrier plate 1112 as described above with reference to FIG. 11 via conduction or induction but the heat then radiates from the carrier plate 1112 to the substrate 114 instead of direct conduction. In this form, the spacers 1210 may optionally be a thermally insulating material to inhibit direct conduction. In another form, not specifically shown, the carrier plate 1112 is omitted and the spacers 1210 space the substrate 114 from the base plate 1110 such that the base plate 1110 directly heats the substrate 114 via radiation instead of conduction.

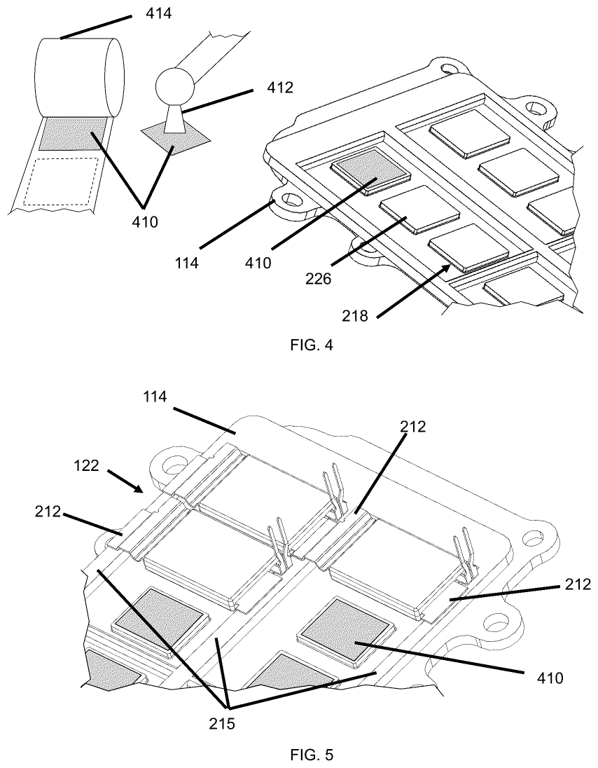

Returning to FIG. 3, after step 302, the method 300 can proceed to step 304. In step 304, a plurality of solder pre-forms 410, shown in FIG. 4, are placed on the substrate 114. In the example provided, each solder pre-form 410 is placed on a top surface 226 of a corresponding one of the pads 218. A tacking agent may optionally be dispensed between the substrate 114 and the solder pre-forms 410 to retain the solder pre-forms 410 in place. In one form, the tacking agent is a flux-less tacking agent that evaporates at temperatures greater than 210 degrees Celsius. Other forms of tacking agents with different evaporation temperatures may be used as well.

In the example provided, each solder pre-form 410 is discrete from each other solder pre-form 410. Each solder pre-form 410 is a solder material that is in solid form and in a predetermined flat shape that substantially corresponds to the shape and size of the bottom surface of each discrete power module 122. As such, each solder pre-form 410 also substantially corresponds to the size and shape of the top surface 226 of each pad 218. In one form, the solder pre-forms 410 have a liquidus temperature of 220 degrees Celsius, though solder materials with other liquidus temperatures can be used.

A robot 412 can place the solder pre-forms 410 on the substrate 114. While the robot 412 is illustrated as a multi-axis robotic arm, the robot 412 can be any suitable robotic device including, but not limited to a pick-and-place gantry system. In the example provided, the robot 412 picks and places each solder pre-form 410 individually. In another form, the robot 412 can be configured to pick and place more than one solder pre-form 410 at a time.

In the example provided, the solder pre-forms 410 are picked by the robot 412 from a spool 414 that unwinds as solder pre-forms 410 are needed, though other configurations may be used, such as an array or tray or other dispenser of solder pre-forms 410, for example.

Returning to FIG. 3, the method 300 can proceed to step 306. The insulation tray 118 is placed on the top surface 220 of the substrate 114 in step 306. In another form, step 306 may precede step 304 such that the insulation tray 118 may be placed on the top surface 220 of the substrate 114 prior to the plurality of solder pre-forms 410 being placed on the substrate 114.

The method 300 can the proceed to step 308. In step 308, each discrete power module 122 of the plurality of discrete power modules 122 is placed on a top surface of a corresponding solder pre-form 410 of the plurality of solder pre-forms 410. In one form, the discrete power modules 122 may be placed by a different robot (not shown; e.g., similar to robot 412) while the robot 412 places the solder pre-forms 410 such that once an individual solder pre-form 410 is placed on the substrate 114 the corresponding discrete power module 122 may be placed on the solder pre-form 410 while the robot 412 is placing the next solder pre-form 410. In another form, the discrete power modules 122 may be placed after all of the solder pre-forms 410 are placed on the substrate. A tacking agent may optionally be provided between each discrete power module 122 and its corresponding solder pre-form 410. In one form, the tacking agent is a flux-less tacking agent that evaporates at temperatures greater than 210 degrees Celsius. Other forms of tacking agents with different evaporation temperatures may be used as well. As shown in FIG. 5, the busbars 212 of the discrete power modules 122 are positioned to above the longitudinal partitions 215 of the insulation tray 118.

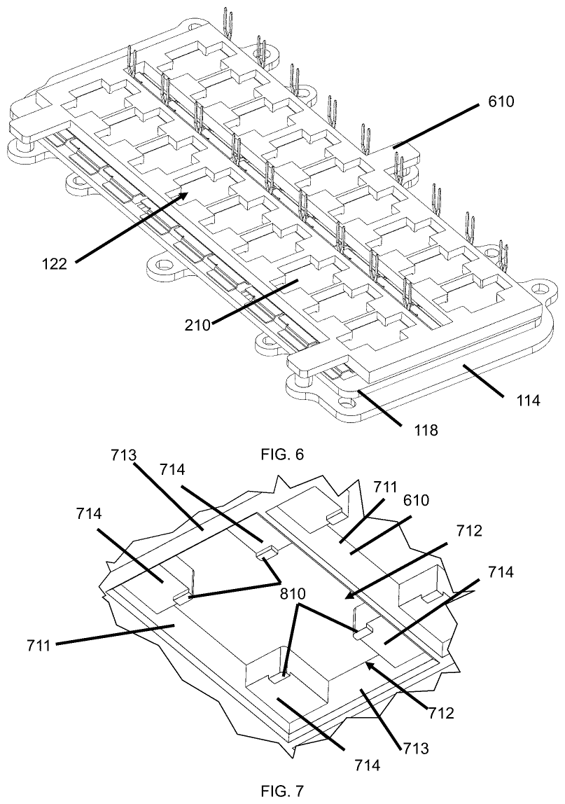

Returning to FIG. 3, the method 300 can proceed to step 310. In step 310, an alignment fixture 610, shown in FIG. 6, is placed over the plurality of discrete power modules 122 and contacts the substrate 114 and the discrete power modules 122. In this position, the alignment fixture 610 does not restrict or contact the insulation tray 118. As shown in FIG. 11, a clamp 614 is positioned above the alignment fixture 610 and applies a force to the alignment fixture 610 toward the substrate 114 such that the alignment fixture 610 clamps the plurality of discrete power module 122 during the reflowing process, described in detail below.

In one form the alignment fixture 610 applies up to 100 psi to the discrete power modules 122. In another variation the alignment fixture 610 applies up to 25 psi to the discrete power modules 122. The amount of pressure the alignment fixture 610 provides can be adjusted based on the specific application requirements. The alignment fixture is described in greater detail below.

Referring to FIGS. 6 and 7, the alignment fixture 610 is configured to retain the discrete power modules 122 in their positions before and during reflow. The alignment fixture 610 includes a plurality of apertures 712 corresponding to the discrete power modules 122. Each aperture 712 aligns with a corresponding one of the discrete power modules 122. Each aperture 712 is open through the top and bottom of the alignment fixture 610 such that at least a portion of the top surface of the housing 210 of each discrete power module 122 is visible through the apertures 712. The alignment fixture 610 is configured to overlap and contact at least a portion of the top surface of each housing 210 proximate the perimeter of each housing 210. In the example provided, each aperture 712 is defined by a pair of longitudinal walls 711 and a pair of lateral walls 713 such that the aperture 712 can be a generally square or rectangular shape, though other configurations can be used.

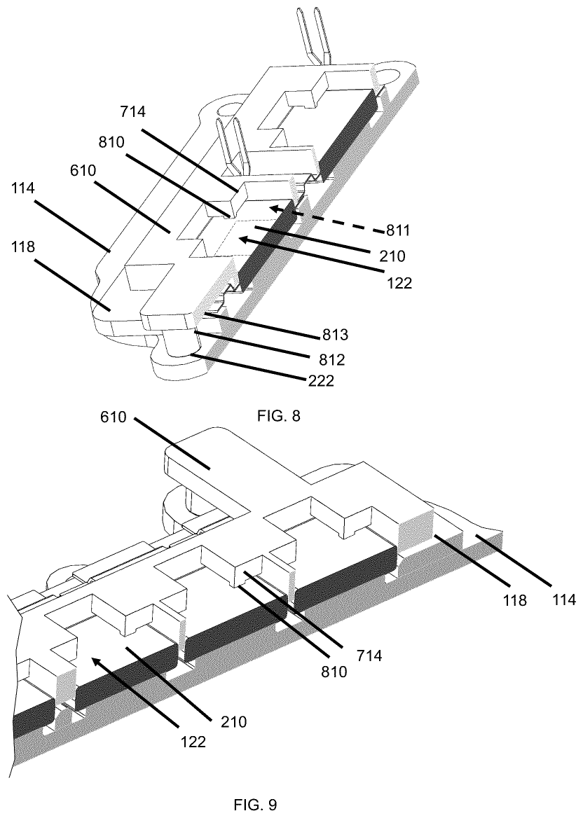

In the example provided, the alignment fixture 610 can include a plurality of protrusions 714 that extend into the apertures 712 from the longitudinal and/or lateral walls 711, 713 to extend over the top surfaces of the housings 210 of the discrete power modules 122. In the example provided, there are four protrusions 714 disposed at the four corners of each aperture 712 to correspond with and overlap the four corners of the housing 210 of the corresponding discrete power module 122. Thus, at least a portion of a perimeter region 811 (FIG. 8) of the top surface of the housing 210 is overlapped by the protrusions 714. In an alternative configuration, not shown, an entirety of the perimeter region 811 (FIG. 8) of the top surface of each housing 210 can be overlapped by the alignment fixture 610.

The alignment fixture 610 may optionally include a plurality of fingers 810. Each finger 810 can extend from a corresponding one of the protrusions 714 in a downward direction to contact the top surface of the housing 210 in the perimeter region 811 (FIG. 8). In the example provided, the fingers 810 are located at the corner of each protrusion 714 that is distal to the longitudinal and lateral walls 711, 713, though other configurations can be used. The fingers 810 provide a smaller contact area than the protrusions 714. The reduced contact area of the fingers 810 can reduce heat transfer between the alignment fixture 610 and the discrete power modules 122.

Referring to FIGS. 8 and 9, the alignment fixture 610 includes a plurality of locating pins 812 that extend in the downward direction from an underside 813 of the alignment fixture 610 toward the substrate 114. Each locating pin 812 is received in a corresponding one of the bores 222 to couple the alignment fixture 610 to the substrate 114 and ensure proper positioning of the alignment fixture 610 on the substrate 114. In the example provided, there are three locating pins 812, though other configurations can be used. The locating pins 812 space the rest of the alignment fixture 610 apart from the substrate 114 to limit thermal conduction between the alignment fixture 610 and the substrate 114. The locating pins 812 may optionally be formed of a thermally insulating material. In one form, the entire alignment fixture 610 is formed of a thermally insulating material. In another form, the locating pins 812 can be a thermally insulating material and the rest of the alignment fixture 610 can be a thermally conductive material.

The locating pins 812 also space the rest of the alignment fixture 610 apart from the insulation tray 118. The spacing between the alignment fixture 610 and the insulation tray 118 is configured to permit thermal expansion of the insulation tray 118 during the reflow process described below with reference to step 312.

Returning to FIG. 3, the method can proceed to step 312 in which the electrical power component 110 then undergoes the reflow process. During the reflow process of step 312, power is provided to the base plate 1110 to heat the substrate 114. The substrate 114 acts as a thermal conductor to melt the solder pre-forms 410. During the reflow process of step 312, at least one sensor 1114, shown in FIG. 11, measures a temperature of a plurality of temperature zones 1116 of the discrete power modules 122. In the example provided, two sensors 1114 are illustrated, but in an alternative form, one sensor 1114 or more than two sensors 1114 may be used. The sensors 1114 detect a temperature at the top surfaces of the housings 210 of the discrete power modules 122. In the example provided, the sensors 1114 are non-contact sensors such as optical sensors (e.g., laser, infrared) for example. In another configuration, the sensors 1114 can be sensors can contact the top surface of the housings 210 (e.g., thermocouples). In the example provided, two temperature zones 1116 are illustrated, but more temperature zones 1116 can be used. Each temperature zone 1116 can be limited to a single one of the power modules 122 or may cover more than one power module 122.

With continued reference to FIG. 11, the sensors 1114 are in communication with a controller 1120. During the reflow process of step 312, the controller 1120 determines whether the measured temperatures of the plurality of temperature zones 1116 are below a threshold temperature. The controller 1120 adjusts the power supplied to the base plate 1110 to maintain the measured temperature each of the plurality of temperature zones 1116 below the threshold temperature throughout the reflowing process of step 312. In other words, if one of the temperature zones 1116 begins to approach the threshold temperature, the controller 1120 can reduce power to the base plate 1110 to reduce the temperature of the entire base plate 1110 to maintain all temperature zones 1116 below the threshold temperature. In an alternative form, the base plate 1110 may have separate heating zones and the controller 1120 may reduce power to a heating zone aligned with the temperature zone 1116 that is approaching the threshold so that that temperature zone 1116 is maintained below the threshold temperature.

In one form the threshold temperature is 260 degrees Celsius. The threshold temperature may be determined based on the maximum operating temperature of the discrete power modules 122 and/or the epoxy molding of the discrete power modules 122.

Since the insulation tray 118 is formed from a non-conductive material and the substrate 114 is formed from a metallic material, the coefficient of thermal expansion between the insulation tray 118 and the substrate 114 are not the same. As such, the space between the insulation tray 118 and the alignment fixture 610 permits the expansion of the insulation tray 118 while the contact between the alignment fixture 610 (e.g., at fingers 810) and the top surfaces of the housings 210 of the discrete power modules 122 inhibits separation of the discrete power modules 122 from the top surfaces 226 of the pads 218. Thus, contact of the solder pre-forms 410 with the pads 218 and the discrete power modules 122 are maintained and package-tilt and bond line planarity issues are inhibited.

In one form, the alignment fixture 610 is formed from a material having a similar coefficient of expansion as the substrate 114. In one form, the coefficient of thermal expansion of the material of the alignment fixture 610 is within ±7*10⁻⁶ m/(m° C.) of the coefficient of thermal expansion of the material of the substrate 114. Additionally, the material of the alignment fixture 610 may have a low thermal conductivity to inhibit heat transfer to the discrete power modules 122. In one form, the alignment fixture 610 is formed from stainless steel. However, other materials with similar coefficients of thermal expansion and low thermal conductivities can be used such as, but not limited to, aluminum graphite for example.

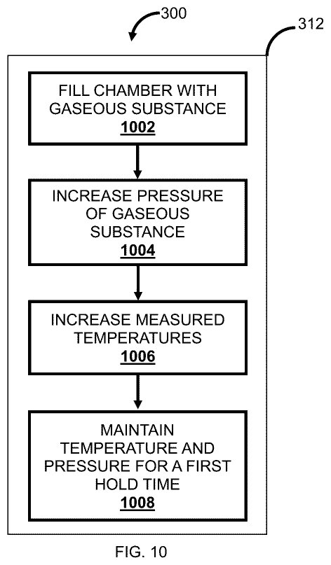

Referring to FIGS. 10 and 11, the reflowing process at step 312 occurs within at least one chamber 1100 and further includes steps provided in FIG. 10. In other words, the steps provided in FIG. 10 illustrate further detail of the step 312 of FIG. 3. At step 1002, the chamber 1100 is evacuated of atmospheric air and is filled with a gaseous substance (e.g., an inert gas like nitrogen), then exchanged for a second gaseous substance. In one form, this second gaseous substance may be a reducing agent such as, but not limited to, formic acid (HCOOH). Formic acid can be activated at temperatures as low as 180 degrees Celsius to perform reduction in a chemical redox reaction and may provide oxidation removal on the solderable surfaces that are barriers to joining the discrete power modules 122 to the substrate 114. Other gases may be used as well, such as forming gases like hydrogen.

After step 1002, the method 300 can proceed to step 1004. In step 1004, the pressure of the gaseous substance is increased. In one form, the gaseous substance is increased to be between 750 mbar and 1050 mbar in the chamber 1100.

In step 1006, the base plate 1110 is powered to be heated to increase the temperature of the substrate 114, as discussed above. The substrate 114 acts as a thermal conductor to melt the solder pre-forms 410, as discussed above. As discussed above, the sensor(s) 1114 measure the temperature of the plurality of temperature zones 1116 of the discrete power modules 122. The sensor(s) 1114 measure the temperatures through the apertures 712.

By increasing the temperature of the substrate 114, the measured temperature of the plurality of temperature zones 1116 is increased. In one form, the base plate 1110 is heated to increase the measured temperatures of the plurality of temperature zones 116 to be between 215 and 260 degrees Celsius.

Step 1006 may occur before or simultaneously with step 1004. Once the temperature zones 1116 are between 215 and 260 degrees Celsius and the pressure is between 750 and 1050 mbar, the measured temperature and pressure are maintained within the desired bounds for a first hold time. In one form, the first hold time may be between one minute and four minutes. Then, a vacuum pump (not shown) evacuates the gasses from the chamber 1100 to create a vacuum environment in the chamber. This vacuum environment is held between 15-90 seconds while the temperature is maintained between 215 and 260 degrees Celsius to significantly reduce the voids at the solder joint. Then, the vacuum is released (e.g., gas such as nitrogen or air is permitted back in the chamber up to atmospheric pressure) the electrical power component 110 is cooled to 20 degrees Celsius to 51 degrees Celsius to allow the solder to re-solidify.

The controller 1120 continuously monitors the temperatures of the temperature zones 1116 and determines whether the measured temperature of the plurality of temperature zones 1116 are below a threshold temperature. As discussed above, the controller 1120 adjusts the power supplied to the base plate 1110 to maintain the measured temperature of the plurality of temperature zones 1116 below the threshold temperature throughout the reflowing process of step 312.

In one form, maintaining the measured temperatures below the threshold includes dynamically adjusting a power supplied to the base plate 1110 to lower a base plate temperature of the base plate 1110. In one variation, the hold time of the base plate temperature may be dynamically adjusted as well.

In another form, maintaining the measured temperature below the threshold includes dynamically decreasing a hold time of a base plate temperature of the base plate. For example, the controller 1120 may maintain the power level to the base plate 1110 but reduce the hold time at that power level. Alternatively, the controller 1120 may reduce the power level and reduce the hold time.

In one form the threshold temperature is 260 degrees Celsius. The threshold temperature may be determined based on the maximum operating temperature of the discrete power modules 122 and/or the epoxy molding of the discrete power modules 122.

Referring back to FIG. 3, in an alternative configuration, step 302 can be performed between at any point before step 312. For example, step 302 may be performed between steps 310 and 312.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method of attaching a plurality of discrete power modules (DPMs) to a substrate, the method comprising:
positioning the substrate such that a bottom surface of the substrate opposes a top surface of a base plate;
placing a plurality of solder pre-forms on a top side of the substrate;
placing each DPM of the plurality of DPMs on a top surface of a corresponding solder pre-form of the plurality of solder pre-forms;
performing a reflowing process that includes:
melting the solder pre-forms by providing heat to the substrate via the base plate;
measuring, via at least one sensor, measured temperatures of a plurality of temperature zones of the DPMs during the reflowing process;
determining, via a controller, whether the measured temperatures of the plurality of temperature zones are below a threshold temperature during the reflowing process; and
maintaining the measured temperatures of the plurality of temperature zones below the threshold temperature during the reflowing process.

2. The method of claim 1, wherein the maintaining the measured temperatures below the threshold includes dynamically adjusting a power supplied to the base plate to lower a base plate temperature of the base plate.

3. The method of claim 2, wherein the maintaining the measured temperature below the threshold further includes dynamically increasing a hold time of the base plate temperature.

4. The method of claim 1, wherein the maintaining the measured temperature below the threshold includes dynamically decreasing a hold time of a base plate temperature of the base plate.

5. The method of claim 1, further comprising:
dispensing a tacking agent:
a) between the top side of a substrate and the plurality of solder pre-forms to retain the plurality of solder pre-forms on the substrate; or
b) between each DPM and the top surface of the corresponding solder pre-forms of the plurality of solder pre-forms to retain the DPMs on the plurality of solder pre-forms; or
c) (a) and (b).

6. The method of claim 1, further comprising placing a tray between the substrate and a plurality of busbars electrically coupled to each of the DPMs of the plurality of DPMs, wherein the tray provides at least one of:
electrical insulation between the busbars and the substrate; and
reaction support for a clamp force applied to the busbars.

7. The method of claim 1, further comprising:
placing an alignment fixture such that the plurality of DPMs are between the alignment fixture and the substrate; and
applying a force to the alignment fixture toward the substrate such that the alignment fixture clamps the plurality of DPMs to the substrate during the reflowing process.

8. The method of claim 7, wherein the substrate is a material having a first coefficient of thermal expansion and the alignment fixture is a material having a second coefficient of thermal expansion, the second coefficient of thermal expansion being within ±7.0*10⁻⁶ m/(m*° C.) of the first coefficient of thermal expansion.

9. The method of claim 7, wherein the alignment fixture defines a plurality of apertures, each aperture of the plurality of apertures aligning with a corresponding DPM of the plurality of DPMs and being open through the alignment fixture such that the DPMs are visible through the apertures, wherein the alignment fixture contacts a plurality of perimeter regions of each DPM.

10. The method of claim 9, wherein the plurality of perimeter regions includes four corners of each DPM.

11. The method of claim 1, wherein the bottom surface of the substrate contacts the top surface of the base plate during the reflowing process.

12. The method of claim 1, wherein the bottom surface of the substrate is disposed a predefined distance above the top surface of the base plate during the reflowing process.

13. The method of claim 1, wherein the at least one sensor includes at least one non-contact sensor.

14. The method of claim 1, wherein the at least one sensor includes three sensors and the plurality of temperature zones includes three temperature zones, wherein each sensor of the three sensors is positioned to measure a corresponding one of the three temperature zones.

15. The method of claim 1, wherein the reflowing process occurs within at least one chamber and the reflowing process further includes:
filling the at least one chamber with a gaseous substance including HCOOH;
increasing a pressure of the gaseous substance to be between 750 and 1050 mbar in the at least one chamber; and
heating the base plate to increase the measured temperatures of the plurality of temperature zones to be between 215 and 265 degrees Celsius for a first hold time while the pressure is between 750 and 1050 mbar.

16. A method of attaching a plurality of discrete power modules (DPMs) to a substrate, the method comprising:
positioning the substrate such that a bottom surface of the substrate opposes a top surface of a base plate;
placing a plurality of solder pre-forms on a top side of the substrate;
placing each DPM of the plurality of DPMs on a top surface of a corresponding solder pre-form of the plurality of solder pre-forms;
performing a reflowing process that includes:
melting the solder pre-forms by providing heat to the substrate via the base plate;
measuring, via at least one sensor, measured temperatures of a plurality of temperature zones of the DPMs during the reflowing process;
determining, via a controller, whether the measured temperatures of the plurality of temperature zones are below a threshold temperature during the reflowing process; and
maintaining the measured temperatures of the plurality of temperature zones below the threshold temperature during the reflowing process by at least one of dynamically adjusting a power supplied to the base plate to lower a base plate temperature of the base plate, and dynamically adjusting a hold time of the power supplied to the base plate.

17. The method of claim 16, further comprising placing a tray between the substrate and a plurality of busbars electrically coupled to each of the DPMs of the plurality of DPMs, wherein the tray provides at least one of:
electrical insulation between the busbars and the substrate; and
reaction support for a clamp force applied to the busbars.

18. The method of claim 16, further comprising:
placing an alignment fixture such that the plurality of DPMs are between the alignment fixture and the substrate; and
applying a force to the alignment fixture toward the substrate such that the alignment fixture clamps the plurality of DPMs to the substrate during the reflowing process.

19. The method of claim 16, wherein the at least one sensor includes three sensors and the plurality of temperature zones includes three temperature zones, wherein each sensor of the three sensors is positioned to measure a corresponding one of the three temperature zones.

20. A system comprising:
a substrate;
a plurality of solder pre-forms disposed on a top side of the substrate;
a plurality of discrete power modules (DPMs), wherein each DPM of the plurality of DPMS is disposed on a corresponding solder pre-form of the plurality of the solder pre-forms, and wherein each DPM includes a plurality of electrical contacts;
an insulation tray disposed between the electrical contacts and the substrate and electrically insulating the electrical contacts from the substrate; and
an alignment fixture disposed on the substrate such that the plurality of DPMs are between the alignment fixture and the substrate, the alignment fixture being configured to clamp the DPMs to the substrate.
